(19) United States
(12) Patent Application Publication
(10) Pub. No.: US 2025/0267878 A1
(43) Pub. Date: Aug. 21, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Young Ock HONG, Gyeonggi-do (KR)

(21) Appl. No.: 18/644,140

(22) Filed: Apr. 24, 2024

(30) Foreign Application Priority Data
Feb. 19, 2024 (KR) 10-2024-0023274

(51) Int. Cl. H10B 80/00; H01L 21/768; H01L 23/00; H01L 23/48; H01L 23/528; H01L 25/00; H01L 25/065; H01L 25/18

(52) U.S. Cl. CPC H10B 80/00; H01L 21/76898; H01L 23/481; H01L 23/5283; H01L 24/08; H01L 24/80; H01L 25/0657; H01L 25/18; H01L 25/50; H01L 2224/08146; H01L 2224/80895; H01L 2224/80896; H01L 2225/06544; H01L 2924/1431; H01L 2924/1434

(57) ABSTRACT

A semiconductor device may include a substrate, a transistor including a gate electrode on the substrate and a junction in the substrate, a through via passing through the substrate through the junction and including a first portion that is in contact with the junction and a second portion extending from the first portion and having a width less than that of the first portion, and an insulating spacer surrounding the second portion of the through via.

### CROSS-REFERENCE TO RELATED APPLICATION

This application claims priority under 35 U.S.C. § 119 to Korean Patent Application No. 10-2024-0023274 filed on Feb. 19, 2024, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

An integration degree of a semiconductor device is mainly determined by a region occupied by a unit memory cell. Recently, as improvements in an integration degree of a semiconductor device in which a memory cell is formed as a single layer on a substrate reach a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a substrate, a transistor including a gate electrode and a gate insulating layer stacked on the substrate and a junction formed in the substrate, a through via passing through the substrate through the junction and including a first portion that is in contact with the junction and a second portion extending from the first portion and having a width less than that of the first portion, and an insulating spacer surrounding the second portion of the through via.

According to an embodiment of the present disclosure, a semiconductor device may include a first wafer including a first substrate and a first transistor, a second wafer including a second substrate and a second transistor, a memory cell array positioned between the first wafer and the second wafer, and a through via passing through the second substrate through a junction of the second transistor and electrically connecting the second transistor and the memory cell array.

According to an embodiment of the present disclosure, a method of manufacturing a semiconductor device may include forming a first wafer including a memory cell array, bonding a second wafer including a substrate to the first wafer, forming a junction in the substrate, forming a contact hole passing through the substrate through the junction, forming an insulating spacer exposing the junction in the contact hole, and forming a through via electrically connecting the junction and the memory cell array, in the contact hole.

According to an embodiment of the present disclosure, a method of manufacturing a semiconductor device may include forming a first bonding layer over a first wafer, forming a second bonding layer over a second wafer including a substrate, bonding the first bonding layer and the second bonding layer to form a bonding structure bonding the first wafer and the second wafer, forming a contact hole passing through the substrate and exposing the bonding structure, rounding a top corner of the contact hole, forming an insulating spacer exposing the rounded top corner, in the contact hole, and forming a through via including a first portion that is in contact with the rounded top corner and a second portion extending from the first portion and having a width less than that of the first portion, in the contact hole.

### BRIEF DESCRIPTION OF THE DRAWINGS

FIGS. 1A and 1B are diagrams illustrating a structure of a semiconductor device according to an embodiment of the present disclosure.

FIGS. 2A to 2C are diagrams illustrating a structure of a semiconductor device according to an embodiment of the present disclosure.

FIGS. 3A to 3C are diagrams illustrating a structure of a semiconductor device according to an embodiment of the present disclosure.

FIGS. 4A to 4E are diagrams illustrating a method of manufacturing a semiconductor device according to an embodiment of the present disclosure.

FIGS. 5A to 5C are diagrams illustrating a method of manufacturing a semiconductor device according to an embodiment of the present disclosure.

FIGS. 6A to 6F are diagrams illustrating a method of manufacturing a semiconductor device according to an embodiment of the present disclosure.

FIG. 7 is a configuration diagram of a semiconductor device according to an embodiment of the present disclosure.

FIG. 8 is a configuration diagram of a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

An integration degree of a semiconductor device may be improved by stacking memory cells in a three dimension. In addition, a semiconductor device with a stable structure and improved reliability may be provided.

Hereinafter, embodiments according to the technical scope of the present disclosure are described with reference to the accompanying drawings.

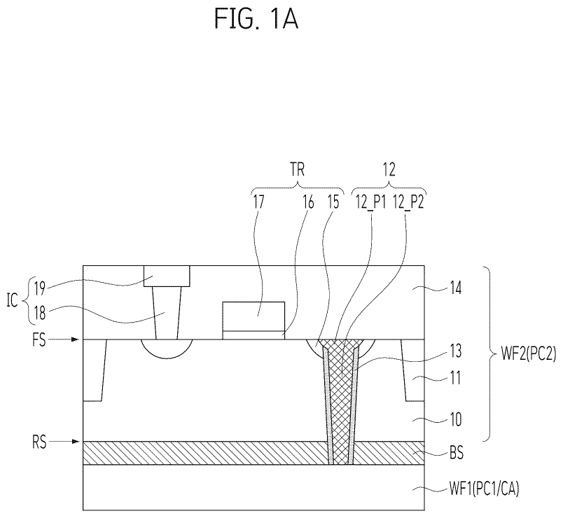

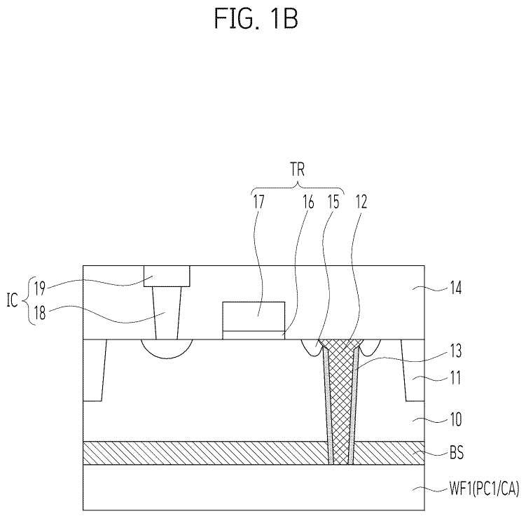

FIGS. 1A and 1B are diagrams illustrating a structure of a semiconductor device according to an embodiment of the present disclosure.

Referring to FIGS. 1A and 1B, the semiconductor device may include a first wafer WF1, a second wafer WF2, and a bonding structure BS. The first wafer WF1 and the second wafer WF2 may be bonded through the bonding structure BS. Here, the first wafer WF1 may include a first peripheral circuit PC1, may include a memory cell array CA, or may include both of the first peripheral circuit PC1 and the memory cell array CA. The second wafer WF2 may include a second peripheral circuit PC2. The bonding structure BS may include a bonding layer, or a bonding pad, or may include both a bonding layer and a bonding pad.

The second wafer WF2 may include a substrate 10, a transistor TR, a through via 12, and an insulating spacer 13. The second wafer WF2 may further include at least one of a bonding structure BS, an isolation layer 11, an interlayer insulating layer 14, and an interconnection structure IC. The bonding structure BS may be positioned over a rear surface RS of the substrate 10. The transistor TR may be positioned on a front surface FS of the substrate 10. The isolation layer 11 may be positioned in the substrate 10, and the transistor TR may be positioned in an active region defined by the isolation layer 11. The transistor TR may include a junction 15, a gate insulating layer 16, and a gate electrode 17. The gate insulating layer 16 and the gate electrode 17 may be positioned on the substrate 10 and may overlap with each other. The gate insulating layer may be interposed between the gate electrode 17 and the substrate 10. The junction 15 may be positioned in the substrate 10.

The through via 12 may pass through the substrate 10 through the junction 15. The through via 12 may include a first portion 12_P1 and a second portion 12_P2. The first portion 12_P1 may be in contact with the junction 15 and may have a hemispherical shape. The second portion 12_P2 may extend from the first portion 12_P1 and may have a width less than that of the first portion 12_P1. The second portion 12_P2 may have a cross-section of a taper shape reducing in size as a distance from the front side FS of the substrate 10 increases.

The through via 12 may extend into the bonding structure BS. In the illustrated embodiment of FIG. 1A, the through via 12 passes through the bonding structure BS and is electrically connected to the first wafer WF1 without a bonding pad. The transistor TR and the first wafer WF1 may be electrically connected through the through via 12. In another embodiment, the through via 12 may be electrically connected to the bonding pad in the bonding structure BS and the transistor TR and the first wafer WF1 may be electrically connected through the though via 12 and the bonding pad.

The insulating spacer 13 may surround at least a portion of the sidewall of the through via 12. For example, as illustrated in FIG. 1A, the insulating spacer 13 may surround only the sidewall of the second portion 12_P2 of the through via 12 and may not surround the sidewall of the first portion 12_P1. Therefore, the through via 12 may be in contact with the junction 15 and may electrically connect the junction 15 to a structure of the first wafer WF1.

The junction 15 may be a region doped with an impurity. The junction 15 may be formed before or after the through via 12 is formed, and may have different shapes according to its formation time point. FIG. 1A illustrates an example where the junction 15 is formed before the formation of the through via 12. As illustrated in FIG. 1A, the junction 15 has a shape surrounding the first portion 12_P1 and has a relatively shallow depth. FIG. 1B illustrates an example where the junction 15 is formed after the formation of the through via 12. Referring to FIG. 1B, the junction 15 may then have a shape protruding from the first portion 12_P1 and may have a relatively deep depth.

The junction 15 may be a source region or a drain region. In an embodiment, the through via 12 may be connected to one of the source region and the drain region, and the interconnection structure IC may be connected to the other one. The interconnection structure IC may include at least one contact plug 18 and at least one line 19. The contact plug 18 may extend vertically through the interlayer insulating layer 14 and may be connected to the junction 15. Both the contact plug 18 and the line 19 may be positioned in the interlayer insulating layer 14. The line 19 may be connected to the junction 15 through the contact plug 18.

According to the structure described above, the first wafer WF1 and the second wafer WF2 may be electrically connected through the through via 12. The memory cell array CA and the transistor TR may be electrically connected through the through via 12. In an embodiment, the first peripheral circuit PC1 and the transistor TR may be electrically connected through the through via 12. Because the through via 12 passes through the substrate 10 through the junction 15, the interconnection structure is simplified. Also, compared to a method in which a via connected to the junction 15 and a via passing through the substrate 10 are separately formed and connected through at least one line, the area occupied by the interconnection structure is reduced substantially.

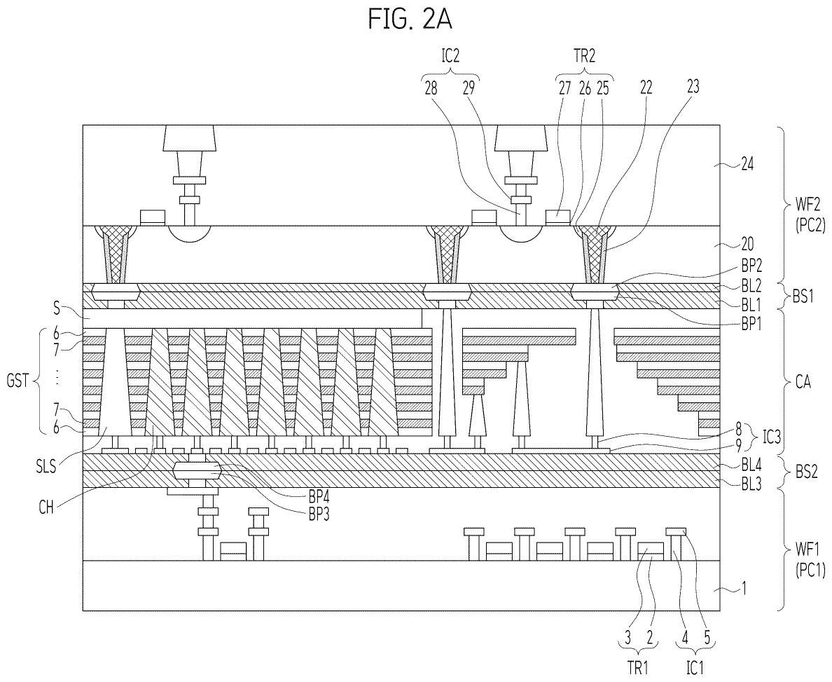

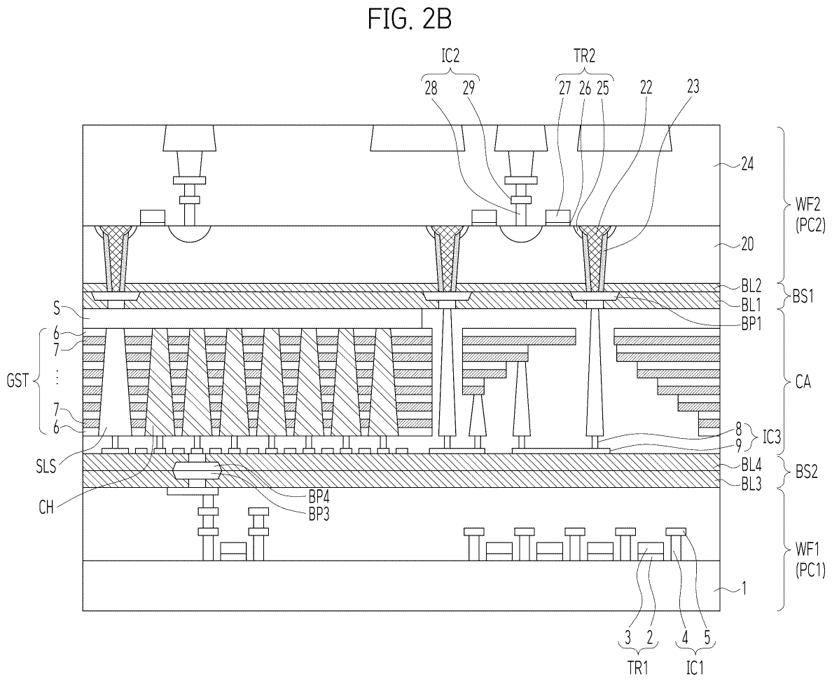

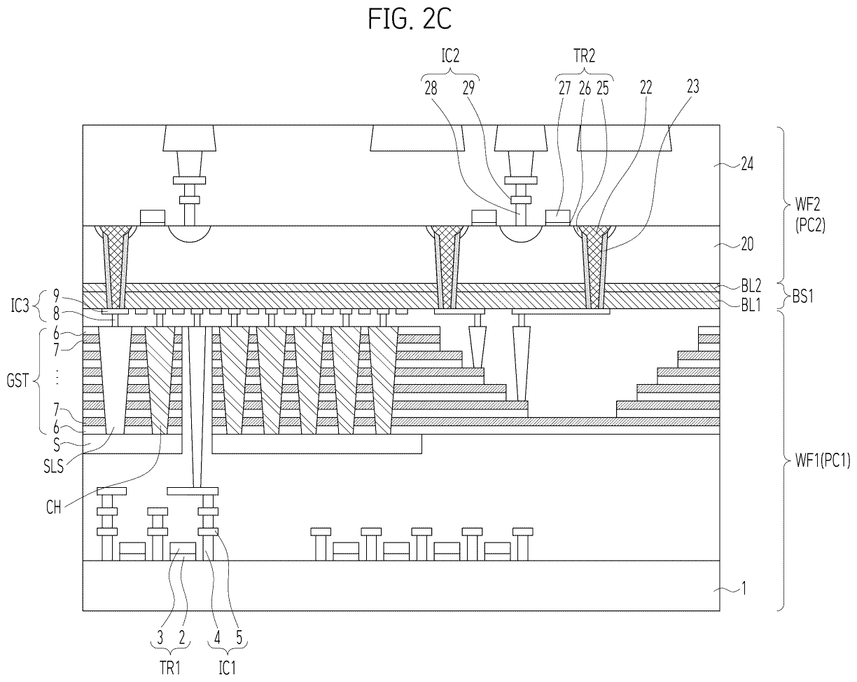

FIGS. 2A to 2C are diagrams illustrating a structure of a semiconductor device according to an embodiment of the present disclosure. Hereinafter, a description that overlaps a content described above may be omitted.

Referring to FIG. 2A, the semiconductor device may include a first wafer WF1, a second wafer WF2, a first bonding structure BS1, a second bonding structure BS2, and a memory cell array CA. The memory cell array CA may be positioned between the first wafer WF1 and the second wafer WF2. The second wafer WF2 and the memory cell array CA may be bonded by the first bonding structure BS1. The first wafer WF1 and the memory cell array CA may be bonded by the second bonding structure BS2.

The first wafer WF1 may be a peripheral circuit chip including a first peripheral circuit. The first wafer WF1 may include a first substrate 1 and a first transistor TR1, and may further include a first interconnection structure IC1. The first transistor TR1 may include a gate insulating layer 2 formed over the first substrate 1 and a gate electrode 3 formed over the gate insulating layer 2. The first interconnection structure IC1 may be electrically connected to the first transistor TR1. For example, the first interconnection structure IC1 may be connected to the source or drain of the transistor TR1. As another example, the first interconnection structure IC1 could be connected to the gate electrode 3 of the first transistor TR1. The first interconnection structure IC1 may include at least one contact plug 4 and at least one line 5.

The second wafer WF2 may be a peripheral circuit chip including a second peripheral circuit. The second wafer WF2 may include a second substrate 20 and at least one second transistor TR2, and may further include at least one second interconnection structure IC2. The at least one second transistor TR2 may include a junction 25, a gate insulating layer 26, and a gate electrode 27. The second interconnection structure IC2 may be connected to the second transistor TR2. The second interconnection structure IC2 may include at least one contact plug 28 and at least one line 29 and may be positioned in an interlayer insulating layer 24 which is disposed over the second substrate 20.

The second wafer WF2 may further include a through via 22 and an insulating spacer 23 covering at least a portion of a sidewall of the through via 22. The through via 22 may be in contact with the junction 25 and may pass through the second substrate 20 through the junction 25. The through via 22 may electrically connect the second transistor TR2 and the memory cell array CA. The through via 22 may include a first portion that is in contact with the junction 25 and a second portion extending from the first portion and having a width less than that of the first portion. In the illustrated embodiment, the insulating spacer 23 surrounds only the second portion of the through via 22.

The memory cell array CA may include a gate structure GST, a plurality of channel structures CH, a source structure S, a slit structure SLS, and a third interconnection structure IC3. The memory cell array CA may or might not include at least a portion of a substrate used as a support in a manufacturing process.

The gate structure GST may include insulating layers 6 and gate lines 7 alternately stacked. The gate structure GST may include an inverted step structure, and a source structure S may be positioned on the gate structure GST. Each of the channel structures CH may extend through the gate structure GST and may be connected to the source structure S. Each of the channel structures CH may include a channel layer, a memory layer, and an insulating core. The plurality of channel structures CH are arranged to be spaced apart from each other within the gat structure GST, each one penetrating through the gate structure GST in a direction perpendicular to a top surface of the gate structure GST. The slit structure SLS may extend through the gate structure GST. The slit structure SLS may include a semiconductor material, an insulating material, or a conductive material. In an embodiment, the slit structure SLS may serve to electrically isolate various regions of the gate structure GST. The channel structures and the slit structure may have a tapered shape.

Memory cells may be positioned in an area where the channel structures CH and the gate lines 7 intersect. The stacked memory cells in each channel structure may configure a memory string. A plurality of memory strings may be connected between a source line and a bit line. A bias for driving the memory cell array CA may be transmitted through the third interconnection structure IC3. The third interconnection structure IC3 may include at least one contact plug 8 and at least one line 9.

The first bonding structure BS1 may be positioned between the memory cell array CA and the second wafer WF2. The first bonding structure BS1 may include a first bonding layer BL1, a second bonding layer BL2, at least one first bonding pad BP1, and at least one second bonding pad BP2. As illustrated in FIG. 2A a plurality of first and second bonding pads BP1 and BP2 may be used. A top surface of the first bonding layer BL1 and a bottom surface of the second bonding layer BL2 may be bonded. The first bonding pads BP1 may be positioned in the first bonding layer BL1. The second bonding pads BP2 may be positioned in the second bonding layer BL2 and may be electrically connected to corresponding first bonding pads BP1. The first and second bonding pads BP1 and BP2 may provide an electrical connection between the second transistor TR2 and the memory cell array CA. The through vias 22 may be electrically connected to a corresponding third interconnection structure IC3 or the source structure S through a pair of aligned first and second bonding pads BP1 and BP2.

The second bonding structure BS2 may be positioned between the memory cell array CA and the first wafer WF1. The second bonding structure BS2 may include a third bonding layer BL3, a fourth bonding layer BL4, at least one third bonding pad BP3, and at least one fourth bonding pad BP4. A top surface of the third bonding layer BL3 and a bottom surface of the fourth bonding layer BL4 may be bonded. The third bonding pad BP3 may be positioned in the third bonding layer BL3. The fourth bonding pad BP4 may be positioned in the fourth bonding layer BL4 and may be electrically connected to the third bonding pad BP3. The third bonding pad BP3 and the fourth bonding pad BP4 may provide an electrical connection between the first transistor TR1 and the memory cell array CA.

The first bonding layer BL1, the second bonding layer BL2, the third bonding layer BL3, and the fourth bonding layer BL4 may include an insulating material forming a Si—O—Si bond by hybrid bonding. In an embodiment, the first bonding layer BL1, the second bonding layer BL2, the third bonding layer BL3, and the fourth bonding layer BL4 may include tetra ethyl ortho silicate (TEOS) or SiCN. The first bonding pad BP1, the second bonding pad BP2, the third bonding pad BP3, and the fourth bonding pad BP4 may include metal such as copper.

Referring to FIG. 2B, the first bonding structure BS1 may include a first bonding layer BL1, a second bonding layer BL2, and at least one first bonding pad BP1. In this case, the through via 22 may pass through the substrate 20 and the second bonding layer BL2, and may be directly connected to the first bonding pad BP1 without at least one second bonding pad.

Referring to FIG. 2C, the semiconductor device may include a first wafer WF1, a second wafer WF2, and a bonding structure BS. The first wafer WF1 may be a memory cell chip including a first peripheral circuit PC1 and a memory cell array CA. The second wafer WF2 may be a peripheral circuit chip including a second peripheral circuit PC2. The first wafer WF1 and the second wafer WF2 may be bonded by the bonding structure BS.

The first wafer WF1 may include a first substrate 1, a first transistor TR1, a first interconnection structure IC1, a gate structure GST, a source structure S, a slit structure SLS, a channel structure CH, and a third interconnection structure IC3. The source structure S may be positioned over the first transistor TR1, and the gate structure GST may be positioned over the source structure S. The gate structure GST may include a step structure. The first interconnection structure IC1 may be electrically connected to the first transistor TR1, and the third interconnection structure IC3 may be electrically connected to the memory cell array CA.

The bonding structure BS may be positioned between the first wafer WF1 and the second wafer WF2. The bonding structure BS may include a first bonding layer BL1 and a second bonding layer BL2. The through via 22 may pass through the second bonding layer BL2 and the first bonding layer BL1 and may be directly connected to the third interconnection structure IC3 without a bonding pad.

According to the structure described above, two or more wafers may be bonded. A peripheral circuit for driving the memory cell array CA may be distributed and disposed on at least two wafers. The second transistor TR2 may be electrically connected to the memory cell array CA using the through via 22, and an interconnection structure may be simplified.

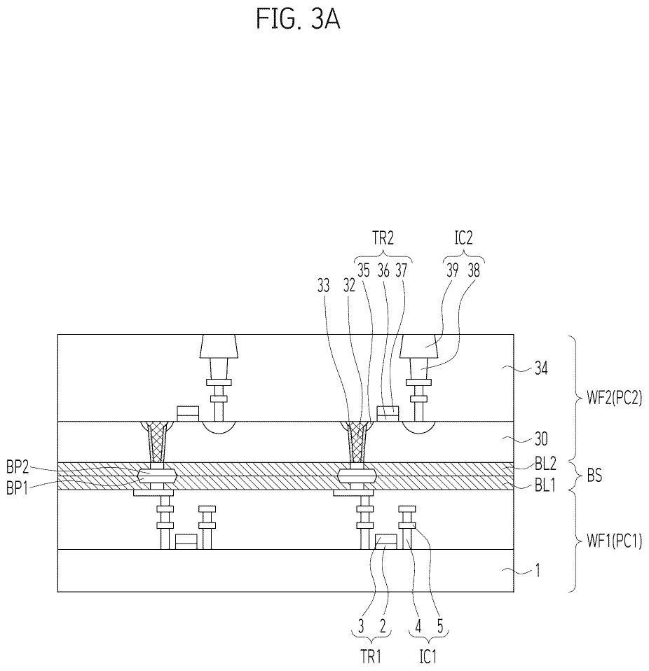

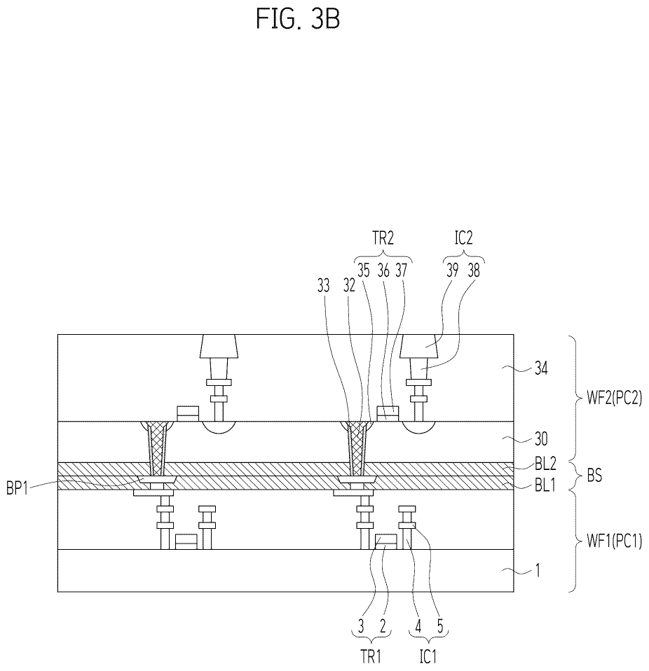

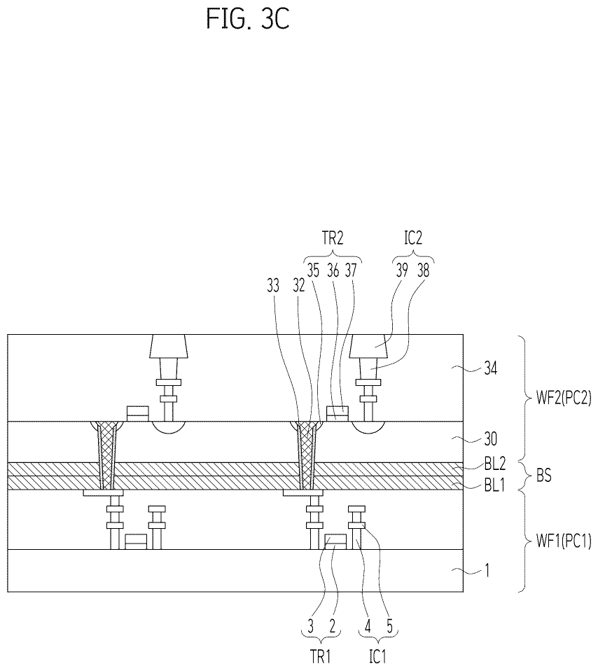

FIGS. 3A to 3C are diagrams illustrating a structure of a semiconductor device according to an embodiment of the present disclosure. Hereinafter, a description that overlaps a content described above may be omitted.

Referring to FIG. 3A, the semiconductor device may include a first wafer WF1, a second wafer WF2, and a bonding structure BS. The first wafer WF1 and the second wafer WF2 may be bonded by the bonding structure BS.

The first wafer WF1 may be a peripheral circuit chip including a first peripheral circuit PC1. The first wafer WF1 may include a first substrate 1 and a first transistor TR1, and may further include a first interconnection structure IC1. The first transistor TR1 may include a gate insulating layer 2 and a gate electrode 3. The first interconnection structure IC1 may be connected to the first transistor TR1. The first interconnection structure IC1 may include at least one contact plug 4 and at least one line 5.

The second wafer WF2 may be a peripheral circuit chip including a second peripheral circuit PC2. The second wafer WF2 may include a second substrate 30 and a second transistor TR2, and may further include a second interconnection IC2 and an interlayer insulating layer 34. The second transistor TR2 may include a junction 35, a gate insulating layer 36, and a gate electrode 37. The second interconnection structure IC2 may be connected to the second transistor TR2. The second interconnection structure IC2 may include at least one contact plug 38 and at least one line 39 and may be positioned in the interlayer insulating layer 34.

The second wafer WF2 may further include a through via 32 and an insulating spacer 33. The through via 32 may be in contact with the junction 35 and may pass through the second substrate 30 through the junction 35.

The first bonding structure BS1 may be positioned between the first wafer WF1 and the second wafer WF2. The first bonding structure BS1 may include a first bonding layer BL1, a second bonding layer BL2, at least one first bonding pad BP1, and at least one second bonding pad BP2. A top surface of the first bonding layer BL1 and a bottom surface of the second bonding layer BL2 may be bonded. The first bonding pad BP1 may be positioned in the first bonding layer BL1. The second bonding pad BP2 may be positioned in the second bonding layer BL2 and may be electrically connected to the first bonding pad BP1. The first bonding pad BP1 and the second bonding pad BP2 may provide an electrical connection between the first peripheral circuit PC1 and the second peripheral circuit PC2. The through via 32 may be electrically connected to the first interconnection structure IC1 through the first bonding pad BP1 and the second bonding pad BP2.

Referring to FIG. 3B, the bonding structure BS may include a first bonding layer BL1, a second bonding layer BL2, and at least one first bonding pad BP1. In this case, the through via 32 may pass through the substrate 30 and the second bonding layer BL2, and may be directly connected to the first bonding pad BP1 without at least one second bonding pad.

Referring to FIG. 3C, the bonding structure BS may include a first bonding layer BL1 and a second bonding layer BL2. The through via 32 may pass through the second bonding layer BL2 and the first bonding layer BL1 and may be directly connected to the first interconnection structure IC1 without a bonding pad.

According to the structure as described above, two or more wafers may be bonded, and peripheral circuit chips may be bonded. The first peripheral circuit PC1 and the second peripheral circuit PC2 may be electrically connected using the through via 32, and an interconnection structure may be simplified.

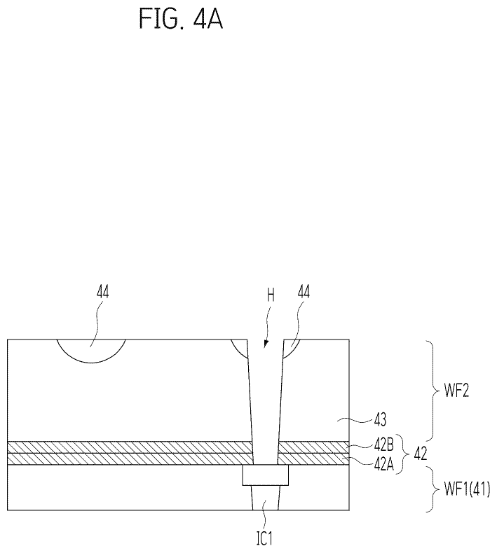

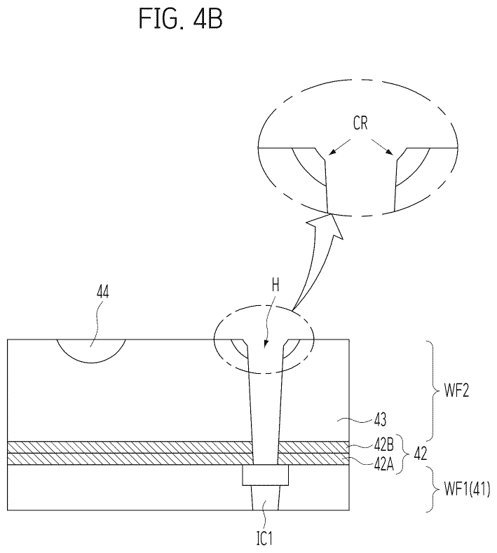

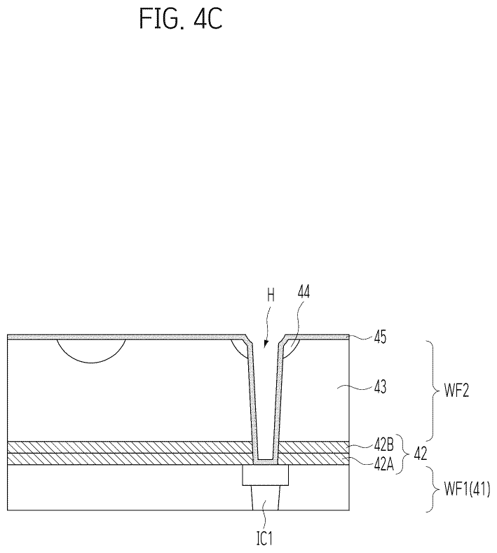

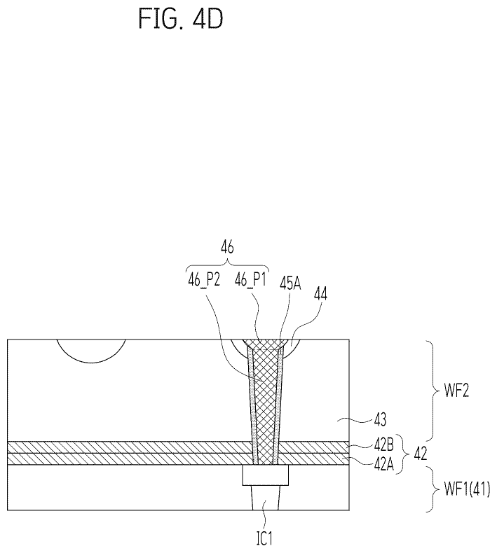

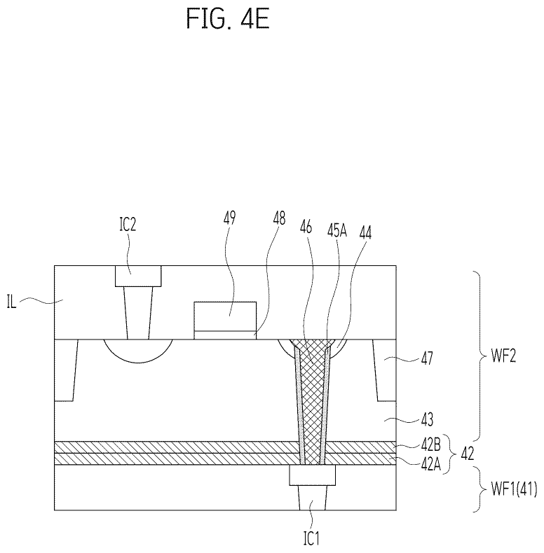

FIGS. 4A to 4E are diagrams illustrating a method of manufacturing a semiconductor device according to an embodiment of the present disclosure. Hereinafter, a description that overlaps a content described above may be omitted.

Referring to FIG. 4A, a first wafer WF1 including a first substrate 41 may be formed. The first wafer WF1 may include a memory cell array and a first interconnection structure IC1 electrically connected to the memory cell array. For reference, the first wafer WF1 may include a peripheral circuit instead of the memory cell array, or may include both of the memory cell array and the peripheral circuit.

Subsequently, a first bonding layer 42A may be formed over the first wafer WF1 and a second bonding layer 42B may be formed over a second wafer WF2 including a second substrate 43. Subsequently, a bonding structure 42 may be formed by bonding the first bonding layer 42A and the second bonding layer 42B. The first wafer WF1 and the second wafer WF2 may be bonded through the bonding structure 42.

Subsequently, a junction 44 may be formed in the second substrate 43. In an embodiment, the junction 44 may be formed by doping an impurity into the second substrate 43. Subsequently, a contact hole H passing through the second substrate 43 through the junction 44 may be formed.

The contact hole H may have a depth exposing at least the bonding structure 42. In an embodiment, the contact hole H may expose at least one first bonding pad in the first bonding layer 42A or may expose at least one second bonding pad in the second bonding layer 42B. In an embodiment, the contact hole H may pass through the bonding structure 42 and expose the first wafer WF1. The contact hole H may expose the first interconnection structure IC1 of the first wafer WF1.

Referring to FIG. 4B, a top corner CR of the contact hole H may be rounded. In an embodiment, when an etching process is used, etching may be concentrated on the top corner CR and an opening width of the contact hole H may be increased. Through this, the junction 44 may be partially etched.

Referring to FIG. 4C, a spacer layer 45 may be formed. The spacer layer 45 may be formed along a profile of the contact hole H. The spacer layer 45 may extend along a top surface of the second substrate 43. In an embodiment, the spacer layer 45 may include an insulating material such as oxide or nitride.

Referring to FIG. 4D, the spacer layer 45 may be etched to form an insulating spacer 45A. A portion of the spacer layer 45 formed on the top surface of the second substrate 43 and a bottom surface of the contact hole H may be etched, by an etching process. In addition, a portion of the spacer layer 45 formed at the top corner CR may be etched. Therefore, the junction 44 may be exposed in the contact hole H.

Subsequently, a through via 46 may be formed in the contact hole H. The through via 46 may be in contact with the junction 44 and may pass through the second substrate 43. The through via 46 may include a first portion 46_P1 and a second portion 46_P2. The first portion 46_P1 may have a relatively large width and may be in contact with the junction 44. The first portion 46_P1 may have a hemispherical shape. The second portion 46_P2 may extend from the first portion 46_P1 and may have a width less than that of the first portion 46_P1. The second portion 46_P2 may have a cross-section of a taper shape.

The junction 44 and the bonding pad in the bonding structure 42 may be electrically connected to each other through the through via 46. Alternatively, the junction 44 and the first interconnection structure IC1 of the first wafer WF1 may be electrically connected by the through via 46. Therefore, the junction 44 and the memory cell array may be electrically connected through the through via 46.

Referring to FIG. 4E, an isolation layer 47 may be formed in the second substrate 43. A gate insulating layer 48 and a gate electrode 49 may be formed. A second interconnection structure IC2 and an interlayer insulating layer IL may be formed.

According to the manufacturing method described above, the junction 44 may be formed after bonding the first wafer WF1 and the second wafer WF2, and the through via 46 passing through the junction 44 may be formed. Therefore, the through via 46 may pass through the second substrate 43 through the junction 44, and a via connected to the junction 44 and a via passing through the second substrate 43 might not be separately formed. A transistor of the second wafer WF2 may be connected to a memory cell array or a peripheral circuit of the first wafer WF1 through the through via 46.

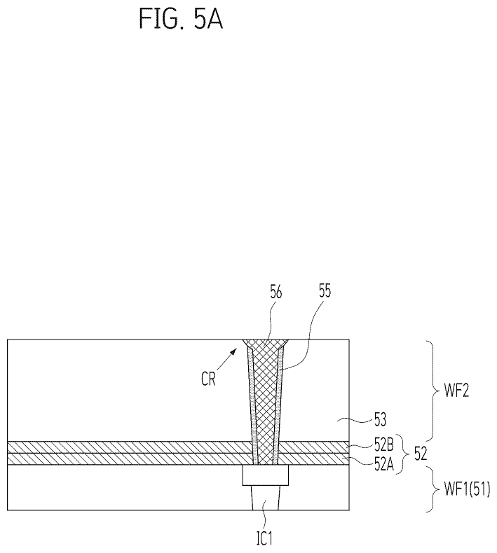

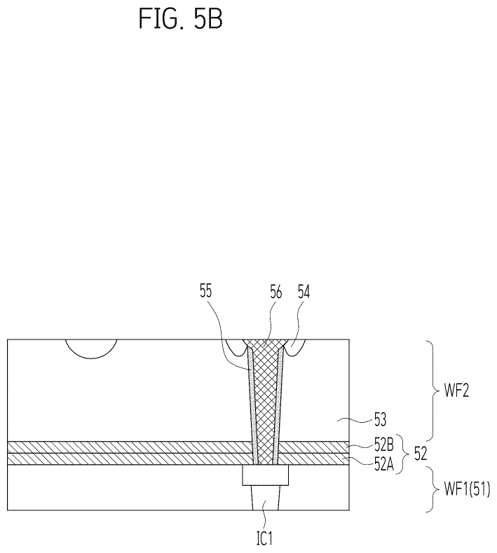

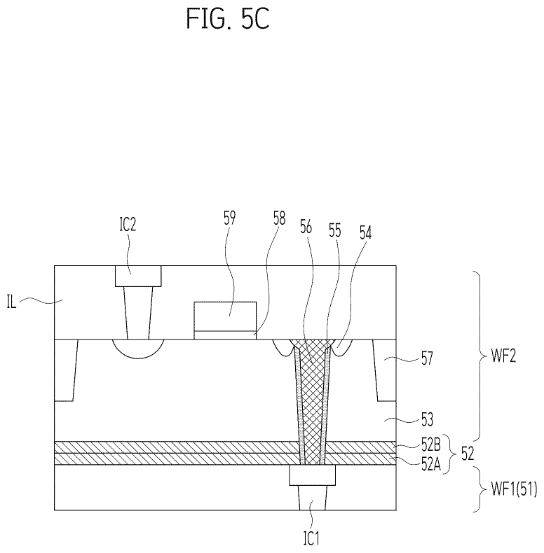

FIGS. 5A to 5C are diagrams illustrating a method of manufacturing a semiconductor device according to an embodiment of the present disclosure. Hereinafter, a description that overlaps a content described above may be omitted.

Referring to FIG. 5A, a first wafer WF1 including a first substrate 51 may be formed. The first wafer WF1 may include a memory cell array and/or a peripheral circuit, and may include a first interconnection structure IC1 electrically connected to the memory cell array and/or the peripheral circuit.

Subsequently, a first bonding layer 52A may be formed over the first wafer WF1. A second bonding layer 52B may be formed over a second wafer WF2 including a second substrate 53. Subsequently, the first bonding layer 52A and the second bonding layer 52B may be bonded. The first wafer WF1 and the second wafer WF2 may be bonded through the bonding structure 52.

Subsequently, a contact hole H may be formed in the second substrate 53. The contact hole H may have a depth exposing at least the bonding structure 52. In an embodiment, the contact hole H may expose a bonding pad in the bonding structure 52. In an embodiment, the contact hole H may pass through the bonding structure 52 and expose the first interconnection structure IC1 of the first wafer WF1.

Subsequently, a top corner CR of the contact hole H may be rounded. Subsequently, an insulating spacer 55 may be formed in the contact hole H. The insulating spacer 55 may be formed on an inner wall of the contact hole H and may expose the rounded top corner CR. Subsequently, a through via 56 may be formed in the contact hole H. The insulating spacer 55 may surround a portion of a sidewall of the through via 56. A top portion of the through via 56 is not surrounded by the insulating spacer 55 so that it is in contact with the rounded top corner CR of the second substrate 53.

Referring to FIG. 5B, a junction 54 may be formed in the second substrate 53. The junction 54 may be formed around the through via 56 by doping an impurity into the second substrate 53. The junction 54 may be formed at the rounded top corner CR.

Referring to FIG. 5C, an isolation layer 57 may be formed in the second substrate 53. A gate insulating layer 58 and a gate electrode 59 may be formed. A second interconnection structure IC2 and an interlayer insulating layer IL may be formed.

According to the manufacturing method described above, the through via 56 may be formed after bonding the first wafer WF1 and the second wafer WF2, and the junction 54 may be formed around the through via 56. Therefore, the through via 56 may pass through the second substrate 53 through the junction 54, and a via connected to the junction 54 and a via passing through the second substrate 53 are not separately formed. A transistor on the second substrate 53 may be connected to a memory cell array or a peripheral circuit of the first wafer WF1 through the through via 56.

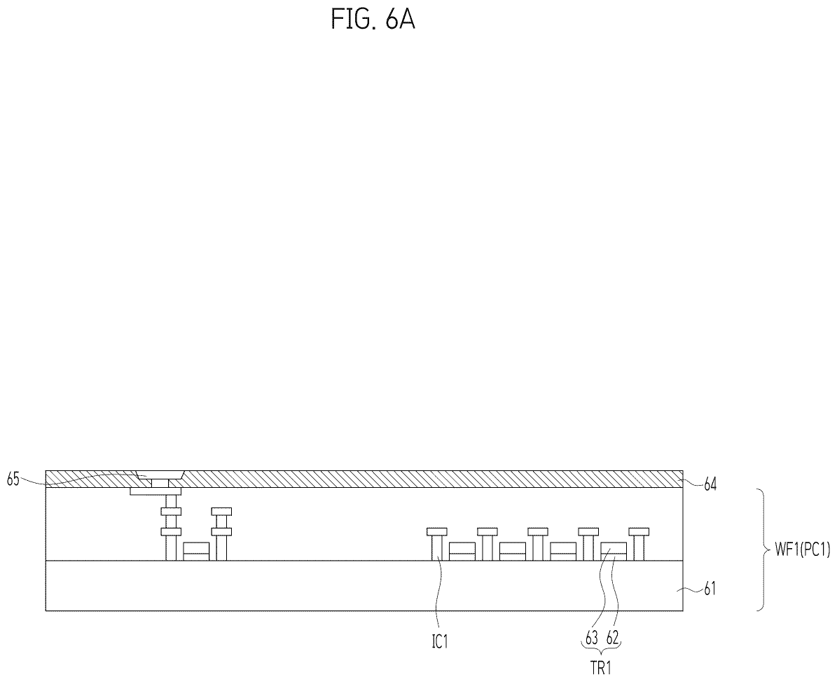

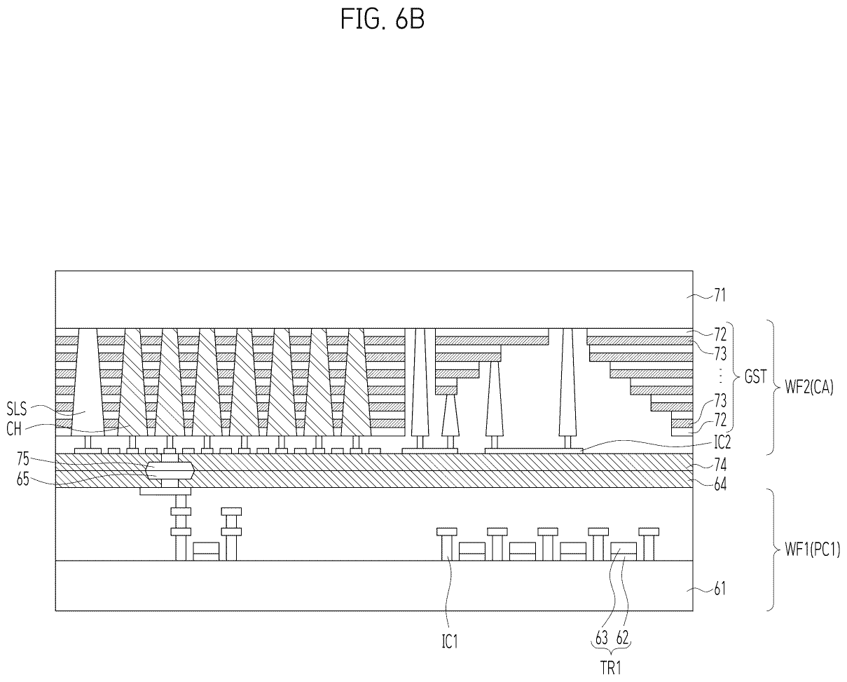

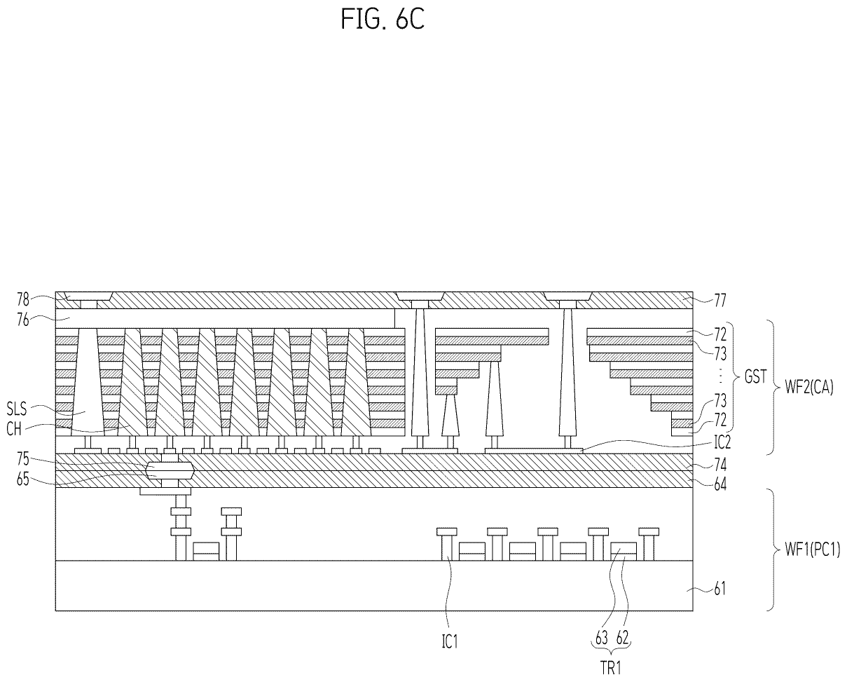

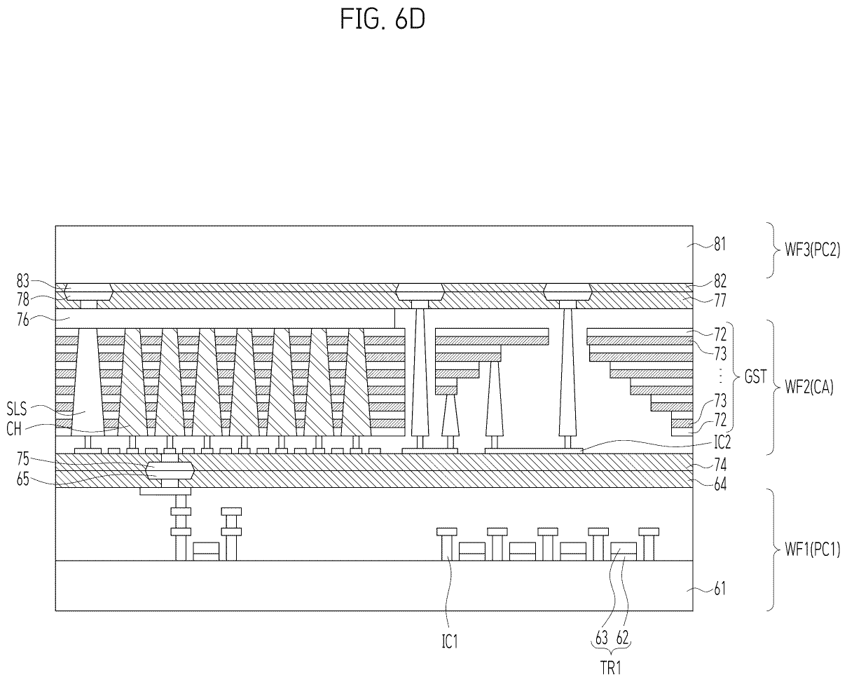

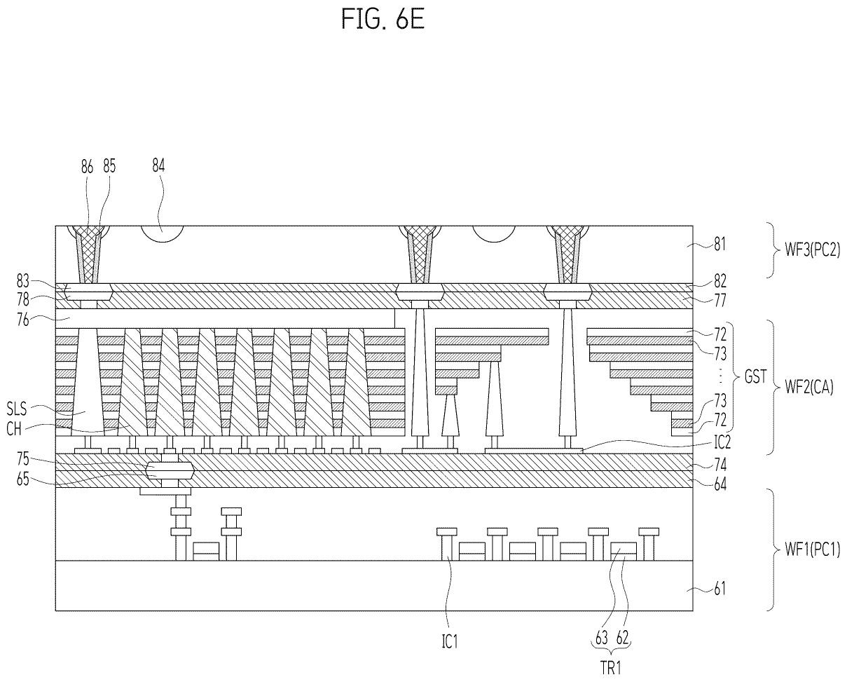

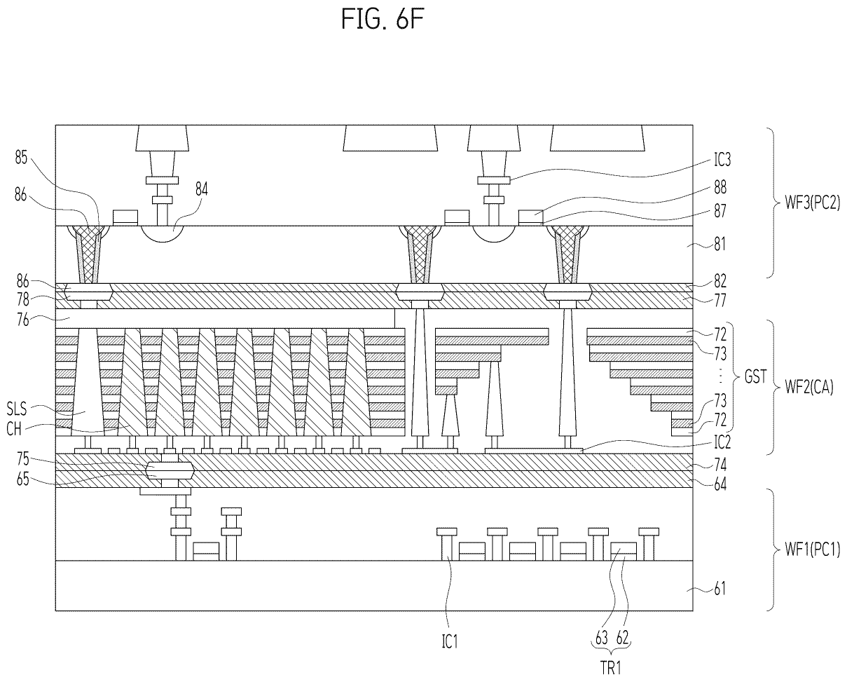

FIGS. 6A to 6F are diagrams illustrating a method of manufacturing a semiconductor device according to an embodiment of the present disclosure. Hereinafter, a description that overlaps a content described above may be omitted.

Referring to FIG. 6A, a first wafer WF1 including a first peripheral circuit PC1 may be formed. The first wafer WF1 may include a first transistor TR1 positioned on a first substrate 61, and the first transistor TR1 may include a gate insulating layer 62 and a gate electrode 63. The first wafer WF1 may include a first interconnection structure IC1 electrically connected to the first peripheral circuit.

Subsequently, a first bonding layer 64 and at least one first bonding pad 65 may be formed over the first wafer WF1. The first bonding pad 65 may be positioned in the first bonding layer 64.

Referring to FIG. 6B, a second wafer WF2 including a memory cell array CA may be formed. The second wafer WF2 may include a gate structure GST positioned over a second substrate 71, and the gate structure GST may include insulating layers 72 and gate lines 73 alternately stacked. The second wafer WF2 may include a plurality of channel structures CH and at least one slit structure SLS extending through the gate structure GST. The second wafer WF2 may include at least one second interconnection structure IC2 connected to a corresponding channel structure CH, a gate line 73, and the like.

Subsequently, a second bonding layer 74 and at least one second bonding pad 75 may be formed over the second wafer WF2. The second bonding pad 75 may be positioned in the second bonding layer 74 and may be electrically connected to the second interconnection structure IC2. Subsequently, the first bonding layer 64 and the second bonding layer 74 may be bonded. The first wafer WF1 and the second wafer WF2 may be bonded in a form in which the gate structure GST is inverted, and the gate structure GST may include an inverted step structure. The first bonding pad 65 and the second bonding pad 75 may be electrically connected.

Referring to FIG. 6C, the second substrate 71 of the second wafer WF2 may be removed to expose a rear surface of the gate structure GST. Subsequently, a source structure 76 may be formed on the rear surface of the gate structure GST. Subsequently, a third bonding layer 77 and at least one third bonding pad 78 may be formed over the second wafer WF2. The third bonding pad 78 may be positioned in the third bonding layer 77 and may be electrically connected to the source structure 76.

Referring to FIG. 6D, a fourth bonding layer 82 and at least one fourth bonding pad 83 may be formed over third wafer WF3 including substrate 81. The fourth bonding layer 82 may be formed over a front surface of the substrate 81, and the fourth bonding pad 83 may be positioned in the fourth bonding layer 82. Subsequently, the third bonding layer 77 and the fourth bonding layer 82 may be bonded to bond the second wafer WF2 and the third wafer WF3. The third bonding pad 78 and the fourth bonding pad 83 may be electrically connected.

Referring to FIG. 6E, a junction 84, an insulating spacer 85, and a through via 86 may be formed on a rear surface of the substrate 81. The through via 86 may be formed after forming the junction 84, or the junction 84 may be formed after forming the through via 86.

Referring to FIG. 6F, a gate insulating layer 87 and a gate electrode 88 may be formed on the rear surface of the substrate 81. Through this, a second peripheral circuit including a transistor may be formed on the rear surface of the substrate 81. Subsequently, a third interconnection structure IC3 electrically connected to the second peripheral circuit may be formed.

According to the manufacturing method described above, a multi-bonded structure may be formed by bonding three or more wafers. The second wafer W2 including the memory cell array CA, the first wafer W1 including the first peripheral circuit PC1, and the third wafer W3 including the second peripheral circuit PC2 may be bonded. In addition, the second peripheral circuit PC2 of the third wafer W3 and the memory cell array CA of the second wafer W2 may be electrically connected using the through via 86.

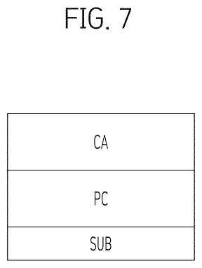

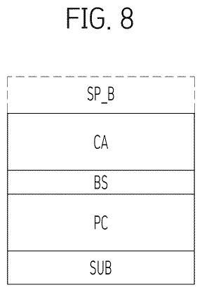

The structure and the manufacturing method according to the above-described embodiments may be applied to semiconductor devices of various structures. FIGS. 7 and 8 illustrate a schematic configuration of a semiconductor device to which the above-described embodiments are applicable.

FIG. 7 is a configuration diagram of a semiconductor device according to an embodiment of the present disclosure.

Referring to FIG. 7, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include at least one contact plug, at least one line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 8 is a configuration diagram of a semiconductor device according to an embodiment of the present disclosure.

Referring to FIG. 8, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 7.

The semiconductor device may have a structure in which the embodiments described above with reference to FIGS. 7 and 8 are combined or may have a partially modified structure. In the embodiment described with reference to FIGS. 7 and 8, positions of the memory cell array CA and the peripheral circuit PC may be changed. At least one memory cell array CA and/or at least one peripheral circuit PC may be additionally bonded to the embodiment described with reference to FIG. 7. In an embodiment, a portion of the peripheral circuitry PC may be disposed in the memory cell array CA.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure, various forms of substitution, modification, change, and combination of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a substrate;
a transistor including a gate electrode and a gate insulating layer stacked on the substrate and a junction formed in the substrate;
a through via passing through the substrate through the junction and including a first portion that is in contact with the junction and a second portion extending from the first portion and having a width less than that of the first portion; and
an insulating spacer surrounding the second portion of the through via.

2. The semiconductor device of claim 1, further comprising:
a memory cell array; and
a bonding structure bonding the memory cell array and the substrate,
wherein the memory cell array is electrically connected to the transistor through the through via.

3. The semiconductor device of claim 1, further comprising:
a first wafer including a peripheral circuit; and
a bonding structure bonding the first wafer and a second wafer including the substrate, the transistor, the through via, and the insulating spacer,
wherein the peripheral circuit is electrically connected to the transistor through the through via.

4. The semiconductor device of claim 1, further comprising:
a first bonding layer;
at least one first bonding pad in the first bonding layer;
a second bonding layer bonded to the first bonding layer; and
at least one second bonding pad positioned in the second bonding layer and electrically connected to the at least one first bonding pad,
wherein the through via is electrically connected to the at least one second bonding pad.

5. The semiconductor device of claim 1, further comprising:
a first bonding layer;
at least one first bonding pad in the first bonding layer; and
a second bonding layer bonded to the first bonding layer,
wherein the through via passes through the second bonding layer and is electrically connected to the at least one first bonding pad.

6. The semiconductor device of claim 1, further comprising:
an interconnection structure;
a first bonding layer over the interconnection structure; and
a second bonding layer bonded to the first bonding layer,
wherein the through via passes through the first bonding layer and the second bonding layer and is electrically connected to the interconnection structure.

7. The semiconductor device of claim 1, wherein the first portion has a hemispherical shape.

8. A semiconductor device comprising:
a first wafer including a first substrate and a first transistor;
a second wafer including a second substrate and a second transistor;
a memory cell array positioned between the first wafer and the second wafer; and
a through via passing through the second substrate through a junction of the second transistor and electrically connecting the second transistor and the memory cell array.

9. The semiconductor device of claim 8, further comprising:
a first bonding structure positioned between the first wafer and the memory cell array; and
a second bonding structure positioned between the second wafer and the memory cell array.

10. The semiconductor device of claim 9, wherein the through via is electrically connected to the memory cell array through a bonding pad in the second bonding structure.

11. The semiconductor device of claim 9, wherein the through via passes through the second bonding structure and is electrically connected to the memory cell array.

12. The semiconductor device of claim 8, wherein the through via includes a first portion that is in contact with the junction and a second portion extending from the first portion and having a width less than that of the first portion.

13. The semiconductor device of claim 12, wherein the first portion has a hemispherical shape.

14. The semiconductor device of claim 12, further comprising:
an insulating spacer surrounding the second portion of the through via.

15. A method of manufacturing a semiconductor device, the method comprising:
forming a first wafer including a memory cell array;
bonding a second wafer including a substrate to the first wafer;
forming a junction in the substrate;
forming a contact hole passing through the substrate through the junction;
forming an insulating spacer exposing the junction in the contact hole; and
forming a through via electrically connecting the junction and the memory cell array, in the contact hole.

16. The method of claim 15, wherein bonding the second wafer to the first wafer comprises:
forming a first bonding layer and at least one first bonding pad over the first wafer;
forming a second bonding layer and at least one second bonding pad over the second wafer; and
bonding the first bonding layer and the second bonding layer.

17. The method of claim 16, wherein forming the contact hole comprises forming the contact hole to expose the at least one second bonding pad.

18. The method of claim 15, wherein bonding the second wafer to the first wafer comprises:
forming a first bonding layer and at least one first bonding pad over the first wafer;
forming a second bonding layer over the second wafer; and
bonding the first bonding layer and the second bonding layer.

19. The method of claim 18, wherein forming the contact hole comprises forming the contact hole passing through the second bonding layer and exposing the at least one first bonding pad.

20. The method of claim 15, wherein bonding the second wafer to the first wafer comprises:
forming a first bonding layer over the first wafer;
forming a second bonding layer over the second wafer; and
bonding the first bonding layer and the second bonding layer.

21. The method of claim 20, wherein forming the contact hole comprises forming the contact hole passing through the first bonding layer and the second bonding layer and exposing an interconnection structure of the first wafer.

22. The method of claim 15, further comprising:
forming a third wafer including a first peripheral circuit; and
bonding the first wafer and the third wafer.

23. The method of claim 15, wherein forming the first wafer comprises:
forming a first peripheral circuit on the substrate; and
forming the memory cell array over the first peripheral circuit.

24. The method of claim 15, further comprising:
rounding a top corner of the contact hole.

25. The method of claim 15, further comprising:
forming a second peripheral circuit on the substrate.

26. A method of manufacturing a semiconductor device, the method comprising:
forming a first bonding layer over a first wafer;
forming a second bonding layer over a second wafer including a substrate;
bonding the first bonding layer and the second bonding layer to form a bonding structure bonding the first wafer and the second wafer;
forming a contact hole passing through the substrate and exposing the bonding structure;
rounding a top corner of the contact hole;
forming an insulating spacer exposing the rounded top corner, in the contact hole; and
forming a through via including a first portion that is in contact with the rounded top corner and a second portion extending from the first portion and having a width less than that of the first portion, in the contact hole.

27. The method of claim 26, further comprising:
forming a junction in the substrate,
wherein the contact hole is formed to pass through the substrate through the junction.

28. The method of claim 26, further comprising:
forming a junction in the substrate around the through via.

29. The method of claim 26, wherein the bonding structure includes a first bonding pad in the first bonding layer and a second bonding pad in the second bonding layer, and
the contact hole exposes the second bonding pad.

30. The method of claim 26, wherein the bonding structure includes a first bonding pad in the first bonding layer, and
the contact hole passing through the second bonding layer and exposing the first bonding pad.

31. The method of claim 26, further comprising:
forming a third wafer including a first peripheral circuit; and
bonding the first wafer and the third wafer.

32. The method of claim 26, wherein forming the first wafer comprises:
forming a first peripheral circuit on the substrate; and
forming a memory cell array over the first peripheral circuit.

33. The method of claim 26, further comprising:
forming a second peripheral circuit on the substrate.
